(19) United States
(12) Patent Application Publication
(10) Pub. No.: US 2025/0349637 A1
(43) Pub. Date: Nov. 13, 2025

(54) SEMICONDUCTOR PACKAGE INCLUDING FILLET STRUCTURE

(71) Applicant: SAMSUNG ELECTRONICS CO., LTD., Suwon-si (KR)

(72) Inventor: Gunho CHANG, Suwon-si (KR)

(73) Assignee: SAMSUNG ELECTRONICS CO., LTD., Suwon-si (KR)

(21) Appl. No.: 18/984,111

(22) Filed: Dec. 17, 2024

(30) Foreign Application Priority Data
May 9, 2024 (KR) 10-2024-0061255

(51) Int. Cl. H01L 23/31; H01L 23/00; H01L 25/07

(52) U.S. Cl. CPC H01L 23/3107; H01L 24/32; H01L 24/33; H01L 25/071; H01L 2224/32145; H01L 2224/33181; H01L 2225/06513; H01L 2225/06541; H01L 2225/06565

(57) ABSTRACT

Provided is a semiconductor package including a first stack including first semiconductor chips that are stacked, a first fillet between the first semiconductor chips, a second stack spaced apart from the first stack and including second semiconductor chips that are stacked, and a second fillet between the second semiconductor chips, wherein each of the first semiconductor chips includes a first side surface facing the second stack, each of the second semiconductor chips includes a third side surface facing the first stack, the first fillet includes a first inner surface on the first side surfaces, the second fillet includes a second inner surface on the third side surfaces, and the first inner surface and the second inner surface are formed flat along a direction that the first semiconductor chips are stacked.

### CROSS-REFERENCE TO RELATED APPLICATION

This application is based on and claims priority to Korean Patent Application No. 10-2024-0061255, filed on May 9, 2024, in the Korean Intellectual Property Office, the disclosure of which is incorporated herein in its entirety by reference.

### BACKGROUND

### 1. Field

Example embodiments relate to a semiconductor package in which a fillet structure surrounding chip stacks.

### 2. Description of Related Art

Due to the development of the electronics industry, demands for higher functionality, higher speed, and smaller electronic components are increasing. In response to the trend, continuously being conducted are development of semiconductor chips with a through silicon via (TSV) structure and semiconductor packages in which the semiconductor chips are stacked.

Meanwhile, in the semiconductor packages, a non-conductive film (NCF) is used between a plurality of semiconductor chips. Due to the NCF between the semiconductor chips, miniaturization of the semiconductor package may be limited.

### SUMMARY

One or more example embodiments of the present disclosure provide a semiconductor package by which warpage due to miniaturization is reduced or disappears.

One or more example embodiments of the present disclosure also provide a semiconductor package by which the reliability is improved.

The technical tasks to be achieved by the example embodiments are not limited to the technical tasks described above, and other technical tasks may be inferred from the following example embodiments by those skilled in the art.

According to one or more example embodiments, there is provided a semiconductor package which may include: a first stack including a plurality of first semiconductor chips that are stacked in a first direction; a first fillet between the plurality of first semiconductor chips; a second stack that is spaced apart from the first stack in a second direction intersecting the first direction, and includes a plurality of second semiconductor chips that are stacked in the first direction; and a second fillet between the plurality of second semiconductor chips, wherein each of the plurality of first semiconductor chips includes a first side surface facing the second stack and a second side surface disposed on an opposite side of the first side surface, wherein each of the plurality of second semiconductor chips includes a third side surface facing the first stack and a fourth side surface disposed on an opposite side of the third side surface, wherein the first fillet includes a first inner surface on at least a portion of the first side surfaces, and facing the second stack, wherein the second fillet includes a second inner surface on at least a portion of the third side surfaces, and facing the first inner surface, and wherein the first inner surface and the second inner surface are flat along the first direction in which the plurality of first semiconductor chips are stacked.

According to one or more example embodiments, there is provided a semiconductor package which may include: a first stack including a plurality of first semiconductor chips that are stacked in a first direction; a first fillet between the plurality of first semiconductor chips; a second stack that is spaced apart from the first stack in a second direction intersecting the first direction, and includes a plurality of second semiconductor chips that are stacked in the first direction; a second fillet between the plurality of second semiconductor chips; and a molding film that surrounds the first stack and the second stack, wherein the molding film includes a separating part between the first stack and the second stack, wherein the separating part extends along the first direction, and wherein the separating part has sides facing the first stack and the second stack are flat.

According to one or more example embodiments, there is provided a semiconductor package which may include: a buffer chip; a first stack on the buffer chip, the first stack including a plurality of first semiconductor chips that are stacked in a first direction; a first fillet on the buffer chip, and the first fillet filling spaces between the plurality of first semiconductor chips; a second stack that is spaced apart from the first stack on the buffer chip in a second direction intersecting the first direction, and includes a plurality of second semiconductor chips that are stacked in the first direction; a second fillet on the buffer chip, and the second fillet filling spaces between the plurality of second semiconductor chips; a molding film that surrounds the first stack and the second stack; and a buffer chip connecting bump on a lower surface of the buffer chip, wherein the buffer chip connecting bump overlaps at least a portion of the first stack or the second stack in the first direction, wherein the first fillet between the buffer chip and the first stack and the second fillet between the buffer chip and the second stack are connected, wherein the molding film includes a separating part extending between the first stack and the second stack along the first direction, wherein a side of the separating part is flat, wherein the separating part is spaced apart from the buffer chip, and wherein the first stack and the second stack are connected to the buffer chip connecting bump.

Additional aspects of the one or more example embodiments will be set forth in part in the description which follows and, in part, will be apparent from the description, or may be learned by practice of the disclosure.

According to one or more example embodiments, it is possible to provide a semiconductor package by which warpage due to the miniaturization is reduced or disappears.

According to one or more example embodiments, it is possible to provide a semiconductor package by which the reliability is improved.

### BRIEF DESCRIPTION

These and/or other aspects, features, and advantages of the invention will become apparent and more readily appreciated from the following description of example embodiments, taken in conjunction with the accompanying drawings of which:

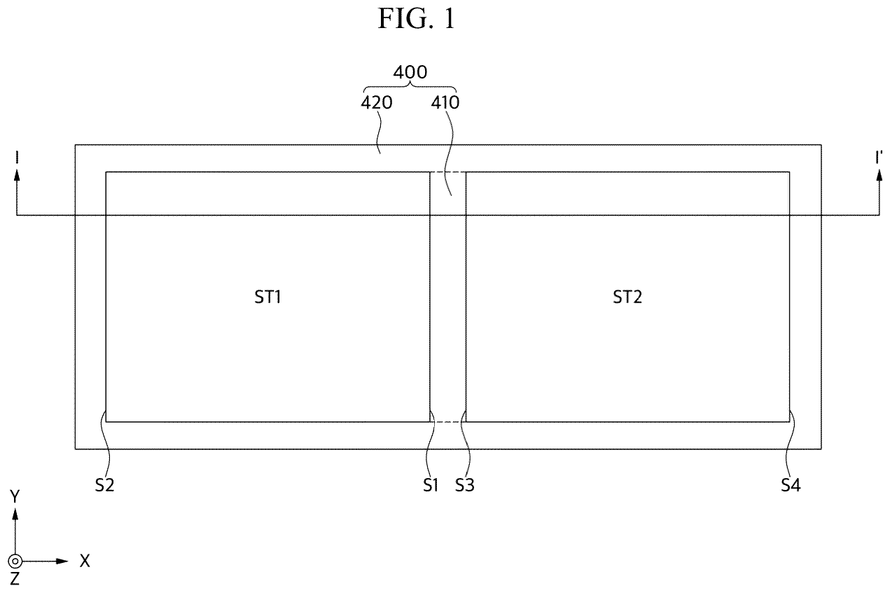

FIG. 1 is a layout diagram of a semiconductor package according to one or more example embodiments;

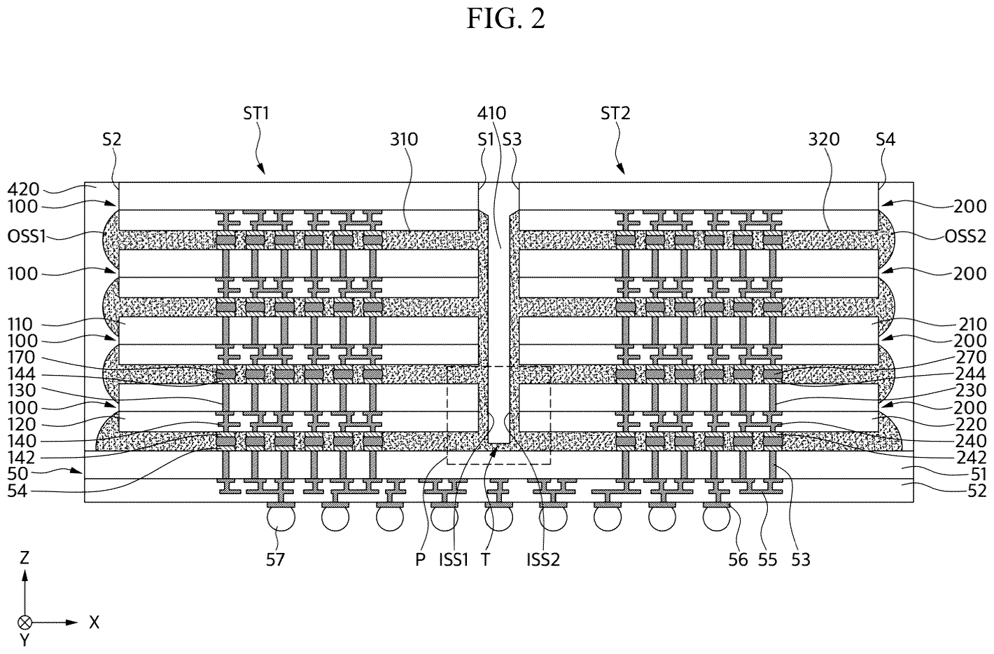

FIG. 2 is a cross-sectional view of the semiconductor package of FIG. 1 taken along a line I-I′ shown in FIG. 1, according to one or more example embodiments;

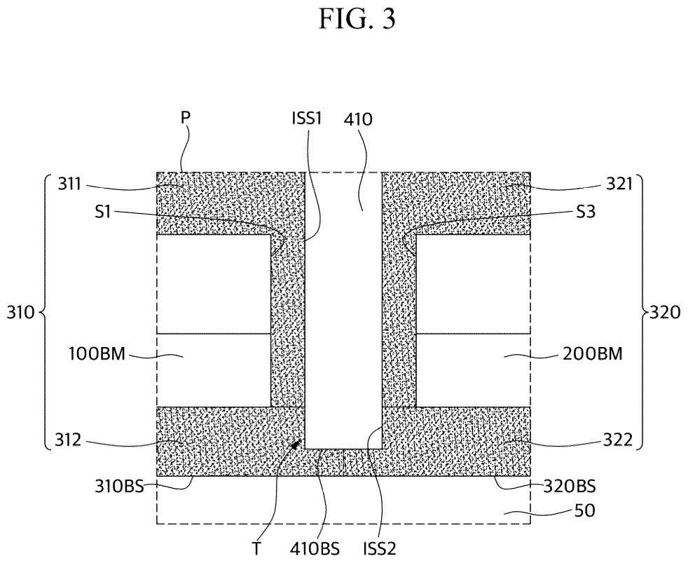

FIG. 3 is an enlarged view illustrating a portion P of the semiconductor package shown in FIG. 2, according to one or more embodiments;

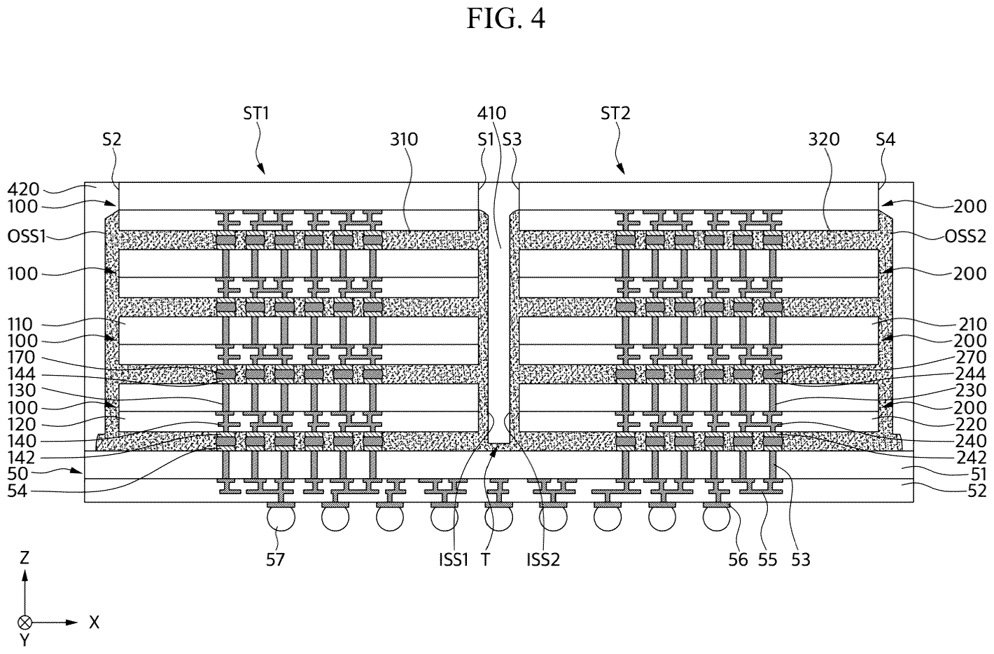

FIG. 4 is a cross-sectional view of a semiconductor package corresponding to FIG. 2, according to one or more example embodiments. For convenience of explanation;

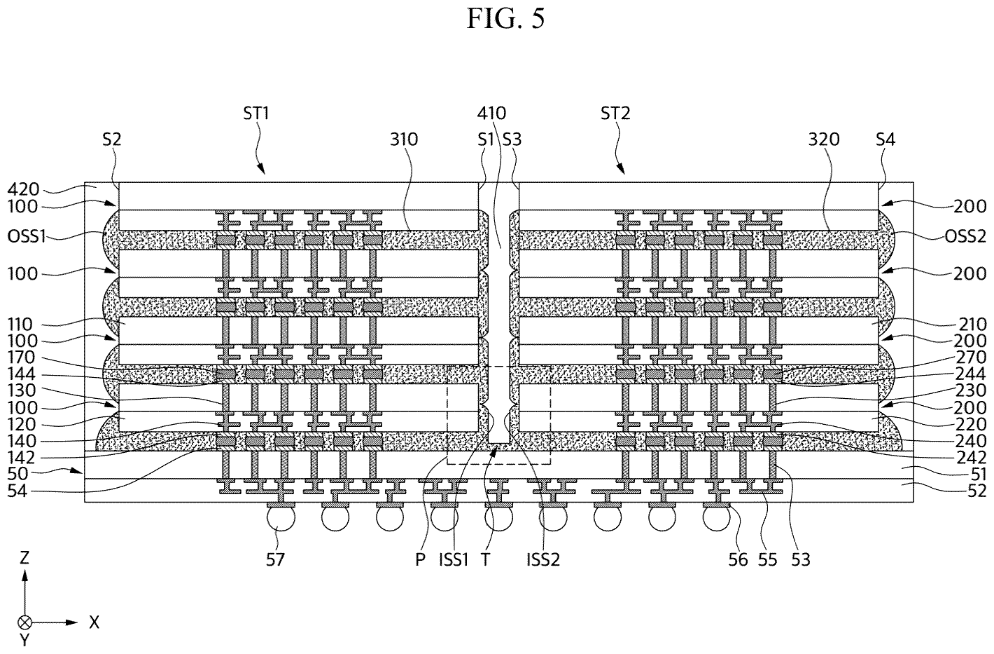

FIG. 5 is a cross-sectional view of a semiconductor package corresponding to FIG. 2, according to one or more example embodiments;

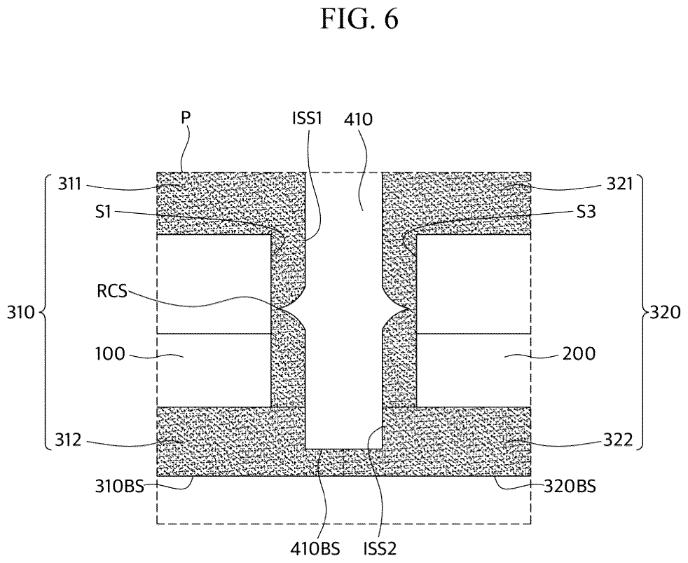

FIG. 6 is an enlarged view illustrating a portion P of the semiconductor package shown in FIG. 5, according to one or more embodiments;

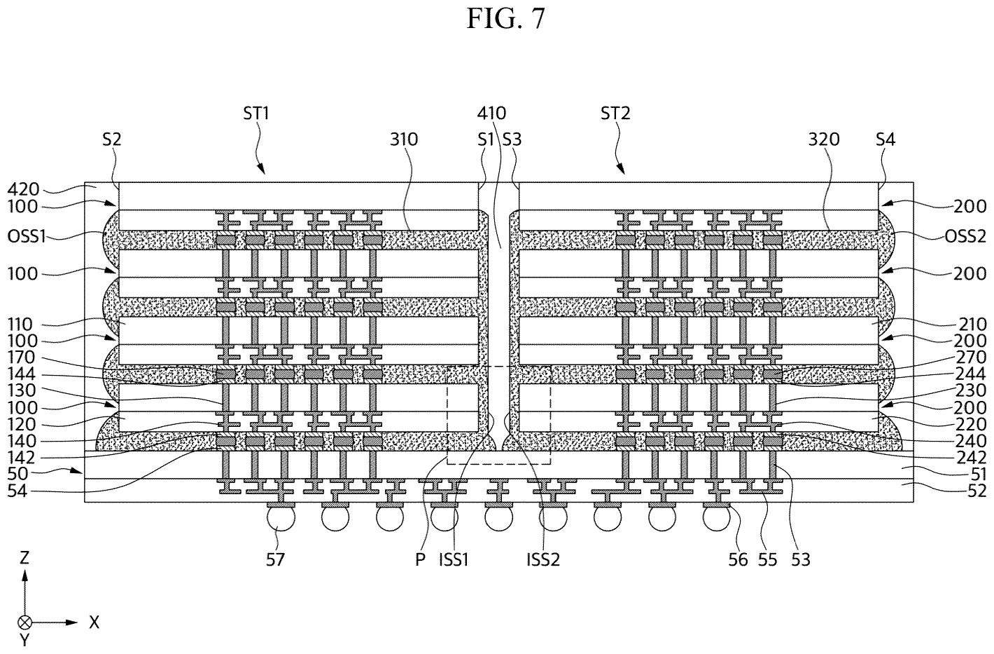

FIG. 7 is a cross-sectional view of a semiconductor package corresponding to FIG. 2, according to one or more example embodiments;

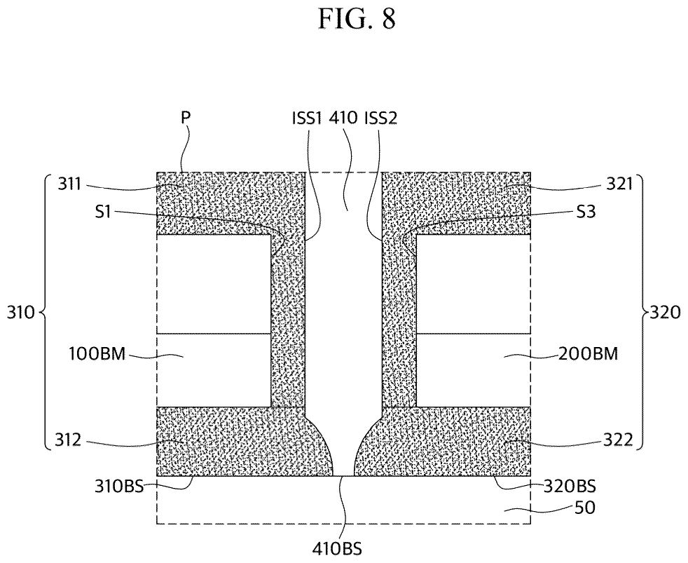

FIG. 8 is an enlarged view illustrating a portion P of the semiconductor package shown in FIG. 7, according to one or more embodiments;

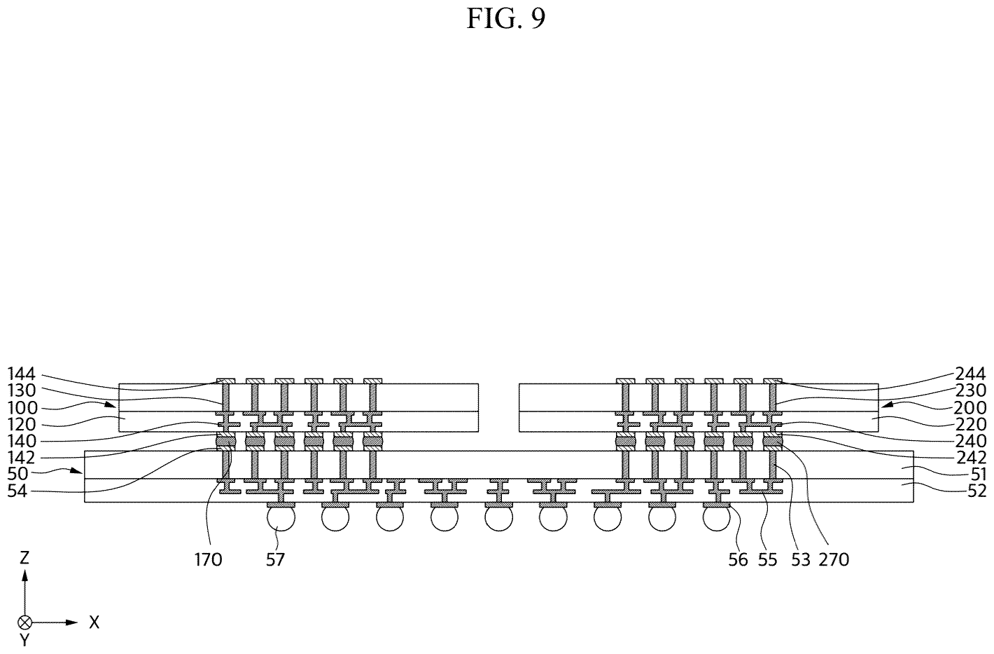

FIGS. 9 to 12 are diagrams illustrating intermediate processes for explaining a method of manufacturing a semiconductor package according to one or more example embodiments; and

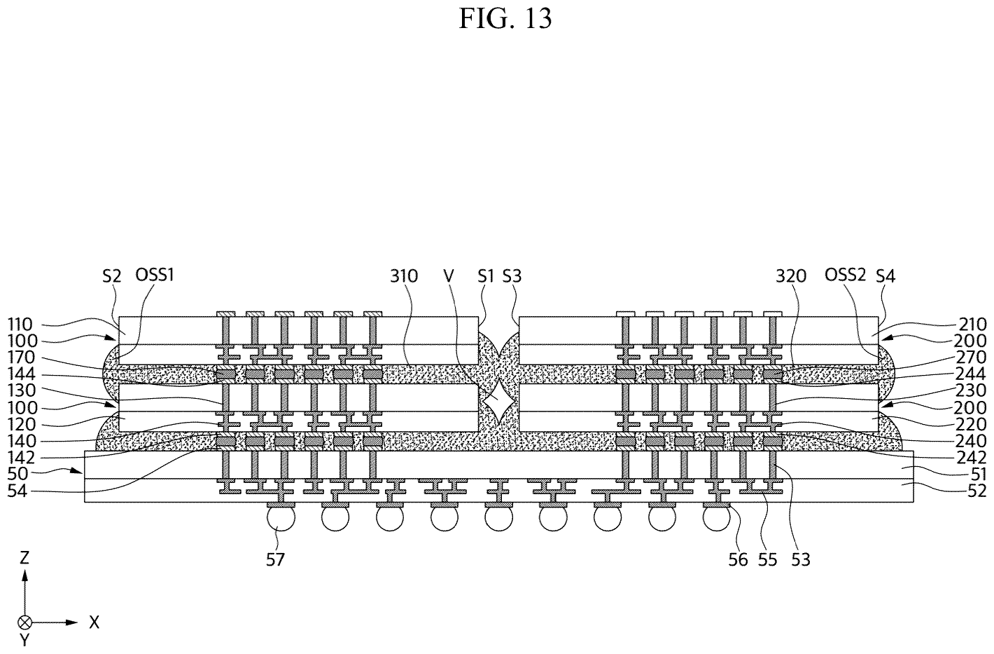

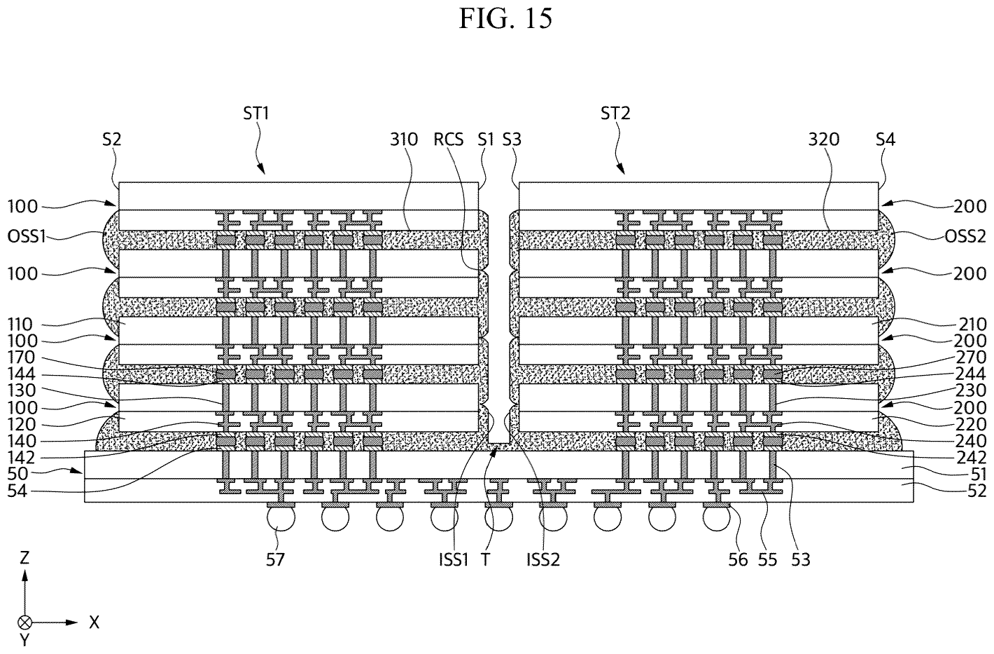

FIGS. 13 to 15 are diagrams illustrating intermediate processes for explaining a method of manufacturing a semiconductor package, according to one or more embodiments.

### DETAILED DESCRIPTION

Prior to the detailed description of the present disclosure, terms or words used in the specification and claims should not be construed as limited to their common or dictionary meanings. Further, the terms or words should be interpreted with meaning and concept consistent with the technical idea of the present disclosure based on the principle that the inventor may appropriately define the concept of terms in order to explain his or her invention in the best way. The embodiments described in this specification and the configurations shown in the drawings are example embodiments of the present disclosure, and do not necessarily represent the entire technical idea of the present disclosure. Accordingly, at the time of filing the present disclosure, there may be various equivalents and modifications that can replace them.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

Further, in the following description, expressions such as an upper side, top, a lower side, bottom, a side, front and a back side are expressed based on the direction shown in the drawing. If the direction of the object changes, it may be expressed differently. The shapes and sizes of elements in the drawings may be exaggerated for clearer explanation.

It will be understood that, although the terms first, second, third, fourth, etc. may be used herein to describe various elements, these elements should not be limited by these terms. These terms are only used to distinguish one element from another element. Thus, a first element described in this description section may be termed a second element or vice versa in the claim section without departing from the teachings of the disclosure.

Hereinafter, various embodiments according to the technical idea of the present disclosure will be described with reference to the attached drawings.

FIG. 1 is a layout diagram of a semiconductor package according to one or more example embodiments. FIG. 2 is a cross-sectional view of the semiconductor package of FIG. 1 taken along a line I-I′ shown in FIG. 1, according to one or more example embodiments. FIG. 3 is an enlarged view illustrating a portion P of the semiconductor package shown in FIG. 2, according to one or more embodiments.

Referring to FIGS. 1 to 3, the semiconductor package may include a buffer chip 50, a first stack ST1, a second stack ST2, a first fillet 310, a second fillet 320 and a molding film 400.

According to one or more example embodiments, the buffer chip 50 may be placed in the bottom part of the first stack ST1 and the second stack ST2. The buffer chip 50 may be electrically connected to the first stack ST1 and the second stack ST2. The first stack ST1 and the second stack ST2 may exchange electrical signals with external devices through the buffer chip 50.

According to one or more example embodiments, the buffer chip 50 may be a logic chip. For example, the buffer chip 50 may be a microprocessor, an analog device, a digital signal processor, or an application processor.

According to one or more example embodiments, the buffer chip 50 may include a buffer chip substrate 51, a buffer chip device layer 52, a buffer chip through via 53, a buffer chip wiring 55, a buffer chip rear surface connecting pad 54 and a buffer chip front surface connecting pad 56.

According to one or more example embodiments, the buffer chip substrate 51 may be bulk silicon or a silicon-on-insulator (SOI). In one or more other example embodiments, the buffer chip substrate 51 may be a silicon substrate. In still one or more other example embodiments, the buffer chip substrate 51 may include silicon germanium, silicon germanium on insulator (SGOI), indium antimonide, lead tellurium compound, indium arsenide, indium phosphide, gallium arsenide, or gallium antimonide. However, the buffer chip substrate 51 is not limited thereto.

According to one or more example embodiments, the buffer chip substrate 51 may include a conductive region, for example, a well doped with an impurity or a structure doped with an impurity. The buffer chip substrate 51 may have various device isolation structures, such as a shallow trench isolation (STI) structure.

According to one or more example embodiments, the buffer chip substrate 51 may be made of at least one material selected from phenol resin, epoxy resin and polyimide. The buffer chip substrate 51 may include at least one substance selected from tetrafunctional epoxy, polyphenylene ether, epoxy/polyphenylene oxide, bismaleimide triazine (BT), thermount, cyanate ester and liquid crystal polymer.

According to one or more example embodiments, the buffer chip substrate 51 may include a resin impregnated into a core material such as glass fiber (glass cloth, glass fabric) along with an inorganic filler, the resin such as prepreg, an ajinomoto build-up film (ABF), FR. −4, and BT.

According to one or more example embodiments, the buffer chip device layer 52 may be placed on the bottom part of the buffer chip substrate 51. The buffer chip device layer 52 may include a plurality of various types of individual devices and an interlayer insulating film. The individual devices may include various microelectronic devices such as a metal-oxide-semiconductor field effect transistor (MOSFET) such as a complementary metal-insulator-semiconductor transistor (a CMOS transistor), system large scale integration (LSI), flash memory, dynamic random access memory (DRAM), static random access memory (SRAM), EEPROM, Phase-change RAM (PRAM), Magnetoresistive RAM (MRAM), Resistive RAM (RRAM), image sensors such as a CMOS imaging sensor (CIS), a micro-electro-mechanical system (MEMS), active devices and passive devices, not being limited thereto.

According to one or more example embodiments, individual devices of the buffer chip device layer 52 may be electrically connected to the conductive region formed within the buffer chip substrate 51. The individual devices on the buffer chip device layer 52 may be electrically separated from other neighboring individual devices by insulating films. Among a plurality of individual devices, the buffer chip device layer 52 may include the buffer chip wiring 55 that electrically connects at least two or a plurality of individual devices and the conductive area of the buffer chip substrate 51.

According to one or more example embodiments, on the buffer chip device layer 52, an insulating layer may be formed to protect the buffer chip wiring 55 and other structures within the buffer chip device layer 52 from external shock or moisture. The insulating layer may expose a portion of the lower surface of the buffer chip front surface connecting pad 56.

According to one or more example embodiments, the buffer chip through via 53 may penetrate the buffer chip substrate 51. The buffer chip through via 53 may extend from an upper surface of the buffer chip substrate 51 toward a lower surface. The buffer chip through via 53 may be connected to the buffer chip wiring 55 provided within the buffer chip device layer 52.

According to one or more example embodiments, the buffer chip through via 53 may include a barrier film formed on a pillar-shaped surface and a buried conductive layer that fills the inside of the barrier film. The barrier film may include at least one of Ti, TiN, Ta, TaN, Ru, Co, Mn, WN, Ni and NiB. However, the barrier film is not limited thereto. The buried conductive layer may include at least one of Cu alloys such as Cu, CuSn, CuMg, CuNi, CuZn, CuPd, CuAu, CuRe and CuW, W, W alloys, Ni, Ru, and Co. However, the buried conductive layer is not limited thereto.

According to one or more example embodiments, an insulating film may be interposed between the buffer chip substrate 51 and the buffer chip through via 53. The insulating film may include an oxide film, a nitride film, a carbonization film, a polymer, or a combination thereof. However, the insulating film is not limited thereto.

According to one or more example embodiments, the buffer chip wiring 55 may include a metal wiring layer and a via plug. For example, the buffer chip wiring 55 may have a multi-layer structure in which two or more metal wiring layers or two or more via plugs are alternately stacked in a third direction Z.

According to one or more example embodiments, the buffer chip front surface connecting pad 56 may be disposed on the buffer chip device layer 52. The buffer chip front surface connecting pad 56 may be electrically connected to the buffer chip wiring 55 inside the buffer chip device layer 52. The buffer chip front surface connecting pad 56 may be electrically connected to the buffer chip through via 53 through the buffer chip wiring 55. The buffer chip front surface connecting pad 56 may include at least one selected from aluminum (Al), copper (Cu), nickel (Ni), tungsten (W), platinum (Pt) and gold (Au).

According to one or more example embodiments, the buffer chip rear surface connecting pad 54 may be placed on the upper surface of the buffer chip 50. The buffer chip front surface connecting pad 56 may be placed on the lower surface of the buffer chip 50. A buffer chip connecting bump 57 may be placed on a bottom part of the buffer chip 50. The buffer chip connecting bump 57 may be disposed on the buffer chip front surface connecting pad 56. For example, the buffer chip connecting bump 57 may be a solder ball or bump.

According to one or more example embodiments, the buffer chip connecting bump 57 may be disposed on the bottom part of the buffer chip 50 to overlap at least a portion of the first stack ST1 or the second stack ST2 in the third direction Z. The buffer chip connecting bump 57 may be electrically connected to the first stack ST1 and the second stack ST2. For example, the buffer chip connecting bump 57 may be electrically connected to a plurality of first semiconductor chips 100 of the first stack ST1 and a plurality of second semiconductor chips 200 of the second stack ST2.

According to one or more example embodiments, the buffer chip rear surface connecting pad 54 may be formed on the upper surface of the buffer chip substrate 51, which is electrically connected to the buffer chip through via 53. The buffer chip rear surface connecting pad 54 may be composed of the same material as the buffer chip front surface connecting pad 56. Not illustrated, but an upper part passivation layer may be formed to surround a portion of a side of the buffer chip rear surface connecting pad 54 on the upper surface of the buffer chip substrate 51.

According to one or more example embodiments, the first stack ST1 may be placed on the buffer chip 50. The first stack ST1 may include the plurality of stacked first semiconductor chips 100. The plurality of first semiconductor chips 100 may be stacked on the buffer chip 50 in the third direction Z. The plurality of first semiconductor chips 100 may include a first bottom part semiconductor chip (100BM) disposed in the lowest part. The first bottom part semiconductor chip (100BM) may be the semiconductor chip placed closest to the buffer chip 50 among the plurality of first semiconductor chips 100 that are stacked.

According to one or more example embodiments, the plurality of first semiconductor chips 100 may be logic chips or memory chips. The plurality of first semiconductor chips 100 may all be the same type of memory chips. For example, the plurality of first semiconductor chips 100 may be volatile memory chips such as DRAM and SRAM. As another example, the plurality of first semiconductor chips 100 may be non-volatile memory chips such as PRAM, MRAM, Ferroelectric RAM (FeRAM) and RRAM. In one or more other example embodiments, the first plurality of semiconductor chips 100 may be high bandwidth memory (HBM).

According to one or more example embodiments, among the plurality of first semiconductor chips 100, one or more chips may be memory chips and one or more other chips may be logic chips. For example, one or more chips of the plurality of first semiconductor chips 100 may be microprocessors, analog devices, digital signal processors and/or application processors.

According to one or more example embodiments, the plurality of first semiconductor chips 100 may be stacked on the buffer chip 50 in the third direction Z, for example, in a vertical direction. The plurality of first semiconductor chips 100 may be electrically connected to each other through a first bump 170, or may be electrically connected to the buffer chip 50.

According to one or more example embodiments, the first fillet 310 may be placed between the plurality of first semiconductor chips 100, for example, two vertically adjacent first semiconductor chips 100. The first fillet 310 may be placed on the bottom part of the plurality of first semiconductor chips 100. The plurality of first semiconductor chips 100 may be attached to each other by the first fillet 310. The first fillet 310 may be placed between the first semiconductor chips 100 that are stacked in the third direction Z. The first fillet 310 may also be placed between the first bottom part semiconductor chip (100BM) and the buffer chip 50. The first fillet 310 may fill a space between the buffer chip 50 and the first stack ST1. The first fillet 310 may include a non-conductive film (NCF).

According to one or more example embodiments, the first fillet 310 may include a first upper part fillet 311 and a first bottom part fillet 312 as shown in FIG. 3. The first upper part fillet 311 may be placed on the first bottom part semiconductor chip (100 BM). The first upper part fillet 311 may be placed above the first bottom part fillet 312. The first bottom part fillet 312 may be placed on a bottom part of the first bottom part semiconductor chip (100BM). For example, the first bottom part fillet 312 may be placed between the first bottom part semiconductor chip (100BM) and the buffer chip 50.

According to one or more example embodiments, the first bottom part fillet 312 may protrude more laterally than the first upper part fillet 311 as shown in FIGS. 2 and 3. The first bottom part fillet 312 may protrude more in a first direction X than the first upper part fillet 311. For example, in the first direction X, the first bottom part fillet 312 may protrude more toward the second stack ST2 than the first upper part fillet 311. As another example, in the first direction X, the first bottom part fillet 312 may protrude further outward toward a cover 420 than the first upper part fillet 311.

According to one or more example embodiments, the first semiconductor chip 100 may include a first semiconductor substrate 110, a first semiconductor device layer 120, a first through via 130, a first front surface connecting pad 142 and a first rear surface connecting pad 144. The first semiconductor chip 100 may be connected to the buffer chip 50 through multiple first bumps 170.

According to one or more example embodiments, the first semiconductor substrate 110 may be bulk silicon or a SOI. In one or more other example embodiments, the first semiconductor substrate 110 may be a silicon substrate. In still one or more other example embodiments, the first semiconductor substrate 110 may include silicon germanium, SGOI, indium antimonide, lead telluride, indium arsenide, indium phosphide, gallium arsenide, or gallium antimonide. However, the first semiconductor substrate 110 is not limited thereto.

According to one or more example embodiments, the first semiconductor substrate 110 may include a conductive region, for example, a well doped with an impurity or a structure doped with an impurity. The first semiconductor substrate 110 may have various device isolation structures, such as an STI structure.

According to one or more example embodiments, the first semiconductor device layer 120 may be placed on a bottom part of the first semiconductor substrate 110. The first semiconductor device layer 120 may include a plurality of various types of individual devices and an interlayer insulating film. The individual devices may include various microelectronic devices such as a MOSFET such as a CMOS transistor, system LSI, flash memory, DRAM, SRAM, EEPROM, PRAM, MRAM, RRAM, image sensors such as a CIS, a MEMS, active devices and passive devices.

According to one or more example embodiments, individual devices of the first semiconductor device layer 120 may be electrically connected to the conductive region formed within the first semiconductor substrate 110. The individual devices in the first semiconductor device layer 120 may be electrically separated from other neighboring individual devices by insulating films. Among the plurality of individual devices, the first semiconductor device layer 120 may include a first wiring structure 140 that electrically connects at least two or a plurality of individual devices and a conductive region of the first semiconductor substrate 110.

According to one or more example embodiments, on the first semiconductor device layer 120, an insulating layer may be formed to protect the first wiring structure 140 and other structures within the first semiconductor device layer 120 from external shock or moisture. The insulating layer may expose a portion of an upper surface of the first front surface connecting pad 142.

According to one or more example embodiments, the first through via 130 may penetrate the first semiconductor substrate 110. The first through via 130 may extend from an upper surface of the first semiconductor substrate 110 toward a lower surface thereof. The first through via 130 may be connected to the first wiring structure 140 provided within the first semiconductor device layer 120.

According to one or more example embodiments, the first through via 130 may include a barrier film formed on a pillar-shaped surface and a buried conductive layer that fills the inside of the barrier film. The barrier film may include at least one of Ti, TiN, Ta, TaN, Ru, Co, Mn, WN, Ni, and NiB. However, the barrier film is not limited thereto. The buried conductive layer may include at least one of Cu alloys such as Cu, CuSn, CuMg, CuNi, CuZn, CuPd, CuAu, CuRe and CuW, W, W alloys, Ni, Ru, and Co. However, the buried conductive layer is not limited thereto.

According to one or more example embodiments, an insulating film may be further interposed between the first semiconductor substrate 110 and the first through via 130. The insulating film may include an oxide film, a nitride film, a carbonization film, a polymer, or a combination thereof. However, the insulating film is not limited thereto.

According to one or more example embodiments, the first wiring structure 140 may include a metal wiring layer and a via plug. For example, the first wiring structure 140 may be a multi-layer structure in which two or more metal wiring layers and two or more via plugs are alternately stacked in the third direction Z.

According to one or more example embodiments, the first front surface connecting pad 142 may be placed on the first semiconductor device layer 120. The first front surface connecting pad 142 may be electrically connected to the first wiring structure 140 inside the first semiconductor device layer 120. The first front surface connecting pad 142 may be electrically connected to the first through via 130 through the first wiring structure 140. The first front surface connecting pad 142 may include at least one selected from aluminum (Al), copper (Cu), nickel (Ni), tungsten (W), platinum (Pt) and gold (Au).

According to one or more example embodiments, the first rear surface connecting pad 144 may be formed on the upper surface of the first semiconductor substrate 110, which is electrically connected to the first through via 130. The first rear surface connecting pad 144 may be composed of the same material as the first front surface connecting pad 142. Not illustrated, but an upper part passivation layer may be formed to surround a portion of the side of the first rear surface connecting pad 144 on the upper surface of the first semiconductor substrate 110.

According to one or more example embodiments, the plurality of first bumps 170 may be placed on a bottom part of the first semiconductor chip 100. The plurality of first bumps 170 may be placed on a front of the first semiconductor chip 100. Here, the front of the first semiconductor chip may refer to a bottom of the first semiconductor chip 100 based on the buffer chip 50. The plurality of first bumps 170 may be disposed in contact with the first front surface connecting pad 142. The plurality of first bumps 170 may electrically connect the first semiconductor chip 100 and the buffer chip 50.

According to one or more example embodiments, the plurality of first bumps 170 may receive at least one of a control signal, a power signal and a ground signal for operation of the first semiconductor chip 100 from the outside. The plurality of first bumps 170 may receive data signals to be stored in the first semiconductor chip 100 from an external source. The plurality of first bumps 170 may externally provide data stored in the first semiconductor chip 100. For example, the plurality of first bumps 170 may be a pillar structure, a ball structure, or a solder layer.

According to one or more example embodiments, in the third direction Z, the first semiconductor chip 100, which is placed farthest from the buffer chip 50, may not include a through via and a rear surface connecting pad, unlike the other first semiconductor chips 100 placed on the bottom part. For example, the first semiconductor chip 100 placed in the upper part based on the buffer chip 50 may not include a through via and a rear surface connecting pad.

FIG. 2 illustrates that the buffer chip 50 is one chip, but the present disclosure is not limited thereto. For example, the buffer chip 50 may be a wiring board for a package. For example, the buffer chip 50 may be a printed circuit board (PCB) or a ceramic wiring board. Alternatively, the buffer chip 50 may be a wiring board for a wafer level package (WLP) manufactured at a wafer level.

FIG. 2 illustrates that the first stack ST1 contains four first semiconductor chips 100, and the second stack ST2 contains four second semiconductor chips 200. However, the present disclosure is not limited thereto. For example, the first stack ST1 and the second stack ST2 may include a plurality of semiconductor chips stacked in different numbers, such as 8 or 12, respectively.

According to one or more example embodiments, the second stack ST2 may be placed spaced apart from the first stack ST1 on the buffer chip 50. For example, the second stack ST2 may be arranged to be spaced apart from the first stack ST1 in the first direction X. The second stack ST2 may include a plurality of second semiconductor chips 200 that are stacked in the third direction Z. The plurality of second semiconductor chips 200 may be stacked on the buffer chip 50 in the third direction Z. The plurality of second semiconductor chips 200 may include a second bottom part semiconductor chip (200BM) disposed in the lowest bottom part. The second bottom part semiconductor chip (200BM) may be the semiconductor chip placed closest to the buffer chip 50 among the plurality of second semiconductor chips 200 stacked. Descriptions regarding the second stack ST2 and the second semiconductor chips 200 are the same as the descriptions of the first stack ST1 and the first semiconductor chips 100, so the descriptions regarding the second stack ST2 and the second semiconductor chips 200 are omitted.

According to one or more example embodiments, the molding film 400 may be formed on the buffer chip 50. The molding film 400 may at least partially cover the first stack ST1, the second stack ST2, the first fillet 310 and the second fillet 320. For example, the molding film 400 may include polymers such as resin. As another example, the molding film 400 may include epoxy molding compounds (EMCs). However, the molding film 400 is not limited thereto.

According to one or more example embodiments, the molding film 400 may surround the first stack ST1 and the second stack ST2. The molding film 400 may be placed on the sides of the first stack ST1 and the second stack ST2. The molding film 400 may not be placed on upper surfaces of the first stack ST1 and the second stack ST2. For example, an upper surface of the molding film 400 may be placed on the same plane as the upper surfaces of the first stack ST1 and the upper surface of the second stack ST2. However, the present disclosure is not limited thereto. For example, the molding film 400 may at least partially cover the upper surface of the first stack ST1 and the upper surface of the second stack ST2.

According to one or more example embodiments, each of the plurality of first semiconductor chips 100 may include a first side surface S1 and a second side surface S2. The first side surface S1 may refer to a side facing the second stack ST2. For example, the first side surface S1 may refer to a surface facing a third side surface S3 of the second semiconductor chip 200, which will be described later. The first side surface S1 may face the plurality of second semiconductor chips 200 of the second stack ST2. The second side surface S2 may refer to a surface disposed on the opposite side of the first side surface S1 in the first direction X. The second side surface S2 may be placed outside of the first side surface S1.

According to one or more example embodiments, each of the plurality of second semiconductor chips 200 may include the third side surface S3 and a fourth side surface S4. The third side surface S3 may refer to a side facing the first stack ST1. For example, the third side surface S3 may refer to a surface facing the first side surface S1. The third side surface S3 may face the plurality of first semiconductor chips 100 of the first stack ST1. The fourth side surface S4 may refer to a surface disposed on the opposite side of the third side surface S3 in the first direction X. The fourth side surface S4 may be placed outside of the third side surface S3.

According to one or more example embodiments, a distance between the first stack ST1 and the second stack ST2 may be 40 μm to 150 μm. For example, in the first direction X where the first stack ST1 and the second stack ST2 are spaced apart, the distance between the first side surface S1 and the third side surface S3 may be 40 μm to 150 μm.

According to one or more example embodiments, the first fillet 310 may cover at least a portion of each of the plurality of first semiconductor chips 100. The first fillet 310 may be disposed on the upper and lower surfaces of the first semiconductor chips 100. For example, the first fillet 310 may be disposed on the entire sides of the first semiconductor chips 100. As another example, the first fillet 310 may be disposed on a part of each side of the first semiconductor chips 100.

According to one or more example embodiments, the first fillet 310 may be disposed on at least a portion of the first side surface S1 and the second side surface S2 of the first semiconductor chip 100. The first fillet 310 may include a first inner surface ISS1 and a first outer surface OSS1. The first inner surface ISS1 may be a surface of the first fillet 310 on the first side surface S1. The first outer surface OSS1 may be a surface of the first fillet 310 on the second side surface S2.

According to one or more example embodiments, the first inner surface ISS1 of the first fillet 310 may be flat. For example, the first inner surface ISS1 may extend flat along the third direction Z in which the plurality of first semiconductor chips 100 are stacked. The first inner surface ISS1 may include a flat surface without any depressions or protrusions.

According to one or more example embodiments, the first outer surface OSS1 of the first fillet 310 may protrude convexly. The first outer surface OSS1 may have a curved shape. The first outer surface OSS1 may protrude more convexly outward than the second side surface S2.

According to one or more example embodiments, in the direction in which the first stack ST1 and the second stack ST2 are spaced apart, a thickness of the first fillet 310 placed on the first side surface S1 may be smaller than a thickness of the first fillet 310 placed on the second side surface S2. For example, in the first direction X, the maximum thickness of the first fillet 310 between the first inner surface ISS1 of the first fillet 310 and the first side surface S1 of the first semiconductor chip 100 may be smaller than the maximum thickness of the first fillet 310 between the first outer surface OSS1 of the first fillet 310 and the second side surface S2 of the first semiconductor chip 100.

According to one or more example embodiments, the second fillet 320 may be placed between the plurality of second semiconductor chips 200. The second fillet 320 may be placed on a bottom part of the plurality of second semiconductor chips 200. The plurality of second semiconductor chips 200 may be attached to each other by the second fillet 320. The second fillet 320 may be disposed between the second semiconductor chips 200 stacked in the third direction Z. The second fillet 320 may also be placed between the second semiconductor chip 200 and the buffer chip 50. The second fillet 320 may fill a space between the buffer chip 50 and the second stack ST2.

According to one or more example embodiments, the second fillet 320 may include a second upper part fillet 321 and a second bottom part fillet 322. The second upper part fillet 321 may be placed on the second bottom part semiconductor chip (200BM). The second upper part fillet 321 may be placed above the second bottom part fillet 322. The second bottom part fillet 322 may be placed in a bottom part of the second bottom part semiconductor chip (200BM). For example, the second bottom part fillet 322 may be placed between the second bottom part semiconductor chip (200BM) and the buffer chip 50.

According to one or more example embodiments, the second bottom part fillet 322 may more protrude to lateral sides than the second upper part fillet 321. The second bottom part fillet 322 may protrude more in the first direction X than the second upper part fillet 321. For example, in the first direction X, the second bottom part fillet 322 may protrude further toward the first stack ST1 than the second upper part fillet 321. As another example, in the first direction X, the second bottom part fillet 322 may protrude further outward toward the cover 420 than the second upper part fillet 321.

According to one or more example embodiments, the second fillet 320 may be disposed at least a portion of each of the plurality of second semiconductor chips 200. The second fillet 320 may be disposed the upper and lower surfaces of the second semiconductor chip 200. For example, the second fillet 320 may be disposed on the entire sides of the second semiconductor chip 200. As another example, the second fillet 320 may be disposed on a part of each side of the second semiconductor chip 200.

According to one or more example embodiments, the second fillet 320 may be disposed on at least a portion of the third side surface S3 and the fourth side surface S4 of the second semiconductor chip 200. The second fillet 320 may include a second inner surface ISS2 and a second outer surface OSS2. The second inner surface ISS2 may be a surface of the second fillet 320 on the third side surface S3. The second outer surface OSS2 may be a surface of the second fillet 320 on the fourth side surface S4.

According to one or more example embodiments, the second inner surface ISS2 of the second fillet 320 may be flat. For example, the second inner surface ISS2 may extend flat along the third direction Z in which the plurality of second semiconductor chips 200 are stacked. The second inner surface ISS2 may include a flat surface without any depressions or protrusions.

According to one or more example embodiments, the second outer surface OSS2 of the second fillet 320 may protrude convexly. The second outer surface OSS2 may have a curved shape. The second outer surface OSS2 may protrude more convexly outward than the fourth side surface S4.

According to one or more example embodiments, in the direction in which the first stack ST1 and the second stack ST2 are spaced part, a thickness of the second fillet 320 placed on the third side surface S3 may be smaller than a thickness of the second fillet 320 placed on the fourth side surface S4. For example, in the first direction X, the maximum thickness of the second fillet 320 between the second inner surface ISS2 of the second fillet 320 and the third side surface S3 of the first semiconductor chip 100 may be smaller than the maximum thickness of the second fillet 320 between the second outer surface OSS2 of the second fillet 320 and the fourth side surface S4 of the second semiconductor chip 200.

According to one or more example embodiments, the molding film 400 may include a separating part 410 and a cover 420. The separating part 410 may be placed between the first stack ST1 and the second stack ST2. For example, the separating part 410 may be placed between the first side surface S1 of the first semiconductor chip 100 and the third side surface S3 of the second semiconductor chip 200. The separating part 410 may be surrounded by the first fillet 310 and the second fillet 320 between the first stack ST1 and the second stack ST2. The cover 420 may be placed outside of the first stack ST1 and the second stack ST2. For example, the cover 420 may be placed on the second side surface S2 of the first semiconductor chip 100 and the fourth side surface S4 of the second semiconductor chip 200.

According to one or more example embodiments, the molding film 400 may fill the space between the first inner surface ISS1 of the first fillet 310 and the second inner surface ISS2 of the second fillet 320. For example, the separating part 410 of the molding film 400 may fill the space between the first inner surface ISS1 of the first fillet 310 and the second inner surface ISS2 of the second fillet 320. A side of the separating part 410 may be flat. Sides of the separating part 410 may face the first stack ST1 and the second stack ST2. The sides of the separating part 410 may be a surface in contact with the first inner surface ISS1 and a surface in contact with the second inner surface ISS2.

According to one or more example embodiments, a trench T may be placed between the first fillet 310 and the second fillet 320. The trench T may be defined by the first inner surface ISS1 of the first fillet 310 and the second inner surface ISS2 of the second fillet 320. The separating part 410 of the molding film 400 may fill the trench T.

According to one or more example embodiments, a bottom surface of the molding film 400 between the first inner surface ISS1 and the second inner surface ISS2 may be placed above a lowest bottom surface 310BS of the first fillet 310 and a lowest bottom surface 320BS of the second fillet 320. The bottom surface of the molding film 400 between the first inner surface ISS1 and the second inner surface ISS2 may be a lowest bottom surface 410BS of the separating part 410 of the molding film 400. The lowest bottom surface 310BS of the first fillet 310 may be a bottom surface of the first bottom part fillet 312. The lowest bottom surface 320BS of the second fillet 320 may be a bottom surface of the second bottom part fillet 322. Based on the buffer chip 50, the lowest bottom surface 410BS of the separating part 410 of the molding film 400 may be placed on a level above a level of the lowest bottom surface 310BS of the first fillet 310 and a level of the lowest bottom surface 320BS of the second fillet 320. The lowest bottom surface 410BS of the separating part 410 of the molding film 400 may be separated from the buffer chip 50.

According to one or more example embodiments, based on the buffer chip 50, the lowest bottom surface 410BS of the separating part 410 of the molding film 400 may be placed on a level below a level of the lower surface of the first bottom part semiconductor chip (100BM) disposed in the lowest bottom part and a level of the lower surface of the second bottom part semiconductor chip (200BM) disposed in the lowest bottom part. For example, in the third direction Z, the lowest bottom surface 410BS of the separating part 410 of the molding film 400 may be placed closer to the buffer chip 50 than the bottom surface of the first bottom part semiconductor chip (100BM) and the bottom surface of the second bottom part semiconductor chip (200BM). However, the present disclosure is not limited thereto. For example, the lowest bottom surface 410BS of the separating part 410 of the molding film 400 may be placed on a level above a level of the lower surface of the first bottom part semiconductor chip (100BM) and a level of the lower surface of the second bottom part semiconductor chip (200BM).

According to one or more example embodiments, the first fillet 310 placed in a bottom part of the first stack ST1 and the second fillet 320 placed in a bottom part of the second stack ST2 may be connected to each other on the buffer chip 50. The first bottom part fillet 312 and the second bottom part fillet 322 may be connected on the buffer chip 50. For example, the first bottom part fillet 312 placed between the first bottom part semiconductor chip (100BM) and the buffer chip 50 and the second bottom part fillet 322 placed between the second bottom part semiconductor chip (200BM) and the buffer chip 50 may be merged or joined. The separating part 410 of the molding film 400 may be placed on the first bottom part fillet 312 and the second bottom part fillet 322 merged on the buffer chip 50.

FIG. 4 is a cross-sectional view of a semiconductor package corresponding to FIG. 2, according to one or more example embodiments. For convenience of explanation, differences from those described with reference to FIGS. 1 to 3 will be mainly described.

Referring to FIG. 4, the first outer surface OSS1 of the first fillet 310 and the second outer surface OSS2 of the second fillet 320 may be flat without being curved. The first outer surface OSS1 and the second outer surface OSS2 may be flat in the direction in which the separating part 410 of the molding film 400 extends. The first outer surface OSS1 and the second outer surface OSS2 may extend flat along the third direction Z. The first outer surface OSS1 and the second outer surface OSS2 may include a flat surface without depressions or protrusions, such as the first inner surface ISS1 and the second inner surface ISS2.

FIG. 5 is a cross-sectional view of a semiconductor package corresponding to FIG. 2, according to one or more example embodiments. FIG. 6 is an enlarged view illustrating a portion P of the semiconductor package shown in FIG. 5, according to one or more embodiments. For convenience of explanation, differences from those described with reference to FIGS. 1 to 3 will be mainly described.

Referring to FIGS. 5 and 6, the first fillet 310 and the second fillet 320 may include one or more recesses RCS. For example, the first fillet 310 may include one or more recesses RCS formed from the first inner surface ISS1 toward the first semiconductor chip 100. The second fillet 320 may include one or more recesses RCS formed from the second inner surface ISS2 toward the second semiconductor chip 200. Outside the one or more recesses RCS, the first inner surface ISS1 and the second inner surface ISS2 may be flat.

According to one or more example embodiments, the separating part 410 of the molding film 400 may fill the one or more recesses RCS. The separating part 410 may be disposed on the first inner surface ISS1, the second inner surface ISS2 and the one or more recesses RCS within the trench T.

FIG. 7 is a cross-sectional view of a semiconductor package corresponding to FIG. 2, according to one or more example embodiments. FIG. 8 is an enlarged view illustrating a portion P of the semiconductor package shown in FIG. 7, according to one or more embodiments. For convenience of explanation, differences from those described with reference to FIGS. 1 to 3 will be mainly described.

Referring to FIGS. 7 and 8, the first fillet 310 placed in the bottom part of the first stack ST1 and the second fillet 320 placed in the bottom part of the second stack ST2 may be spaced apart on the buffer chip 50. For example, separated may be the first bottom part fillet 312 placed between the first bottom part semiconductor chip (100BM) and the buffer chip 50 and the second bottom part fillet 322 placed between the second bottom part semiconductor chip (200BM) placed in the lowest bottom part and the buffer chip 50. The separating part 410 of the molding film 400 may be placed between the first bottom part fillet 312 and the second bottom part fillet 322 spaced apart on the buffer chip 50.

According to one or more example embodiments, the first bottom part fillet 312 may protrude toward the second stack ST2 more than the first inner surface ISS1. The first bottom part fillet 312 disposed in the bottom part of the first bottom part semiconductor chip (100BM) may protrude laterally more than the first upper part fillet 311. For example, an end of the lowest bottom surface 310BS of the first fillet 310 may protrude more than the first inner surface ISS1 toward the second bottom part fillet 322 and may be placed closer to the second inner surface ISS2. Here, the end of the lowest bottom surface 310BS of the first fillet 310 may be an end of the first bottom part fillet 312, and the first inner surface ISS1 may be a side of the first upper part fillet 311 facing the second inner surface ISS2.

According to one or more example embodiments, the second bottom part fillet 322 may protrude toward the first stack ST1 more than the second inner surface ISS2. The second bottom part fillet 322 disposed in the bottom part of the second bottom part semiconductor chip (200BM) may protrude laterally more than the second upper part fillet 321. For example, an end of the lowest bottom surface 320BS of the second fillet 320 may protrude more than the second inner surface ISS2 toward the first bottom part fillet 312, and may be placed closer to the first inner surface ISS1. Here, the end of the lowest bottom surface 320BS of the second fillet 320 may be an end of the second bottom part fillet 322, and the second inner surface ISS2 may be a side of the second upper part fillet 321 facing the first inner surface ISS1.

According to one or more example embodiments, the lowest bottom surface 410BS of the separating part 410 of the molding film 400 may be disposed to be coplanar with the lowest bottom surface 310BS for the first fillet 310 and the lowest bottom surface 320BS for the second fillet 320. The separating part 410 may contact the buffer chip 50 between the first fillet 310 and the second fillet 320.

FIGS. 9 to 12 are diagrams illustrating intermediate processes for explaining a method of manufacturing a semiconductor package, according to one or more example embodiments. For reference, FIGS. 9 to 12 are diagrams for explaining a method of manufacturing the semiconductor package illustrated in FIG. 2.

Referring to FIG. 9, the first semiconductor chips 100 and the second semiconductor chips 200 may be formed on the buffer chip 50.

According to one or more example embodiments, each of the first semiconductor chips 100 and the second semiconductor chips 200 may be connected to the buffer chip 50 through flip-chip bonding. However, the present disclosure is not limited thereto. The method of bonding the first semiconductor chips 100 and the second semiconductor chips 200 to the buffer chip 50 may vary depending on one or more example embodiments. Each of the first semiconductor chips 100 and the second semiconductor chips 200 may be electrically connected to the buffer chip wiring 55 and the buffer chip connecting bump 57.

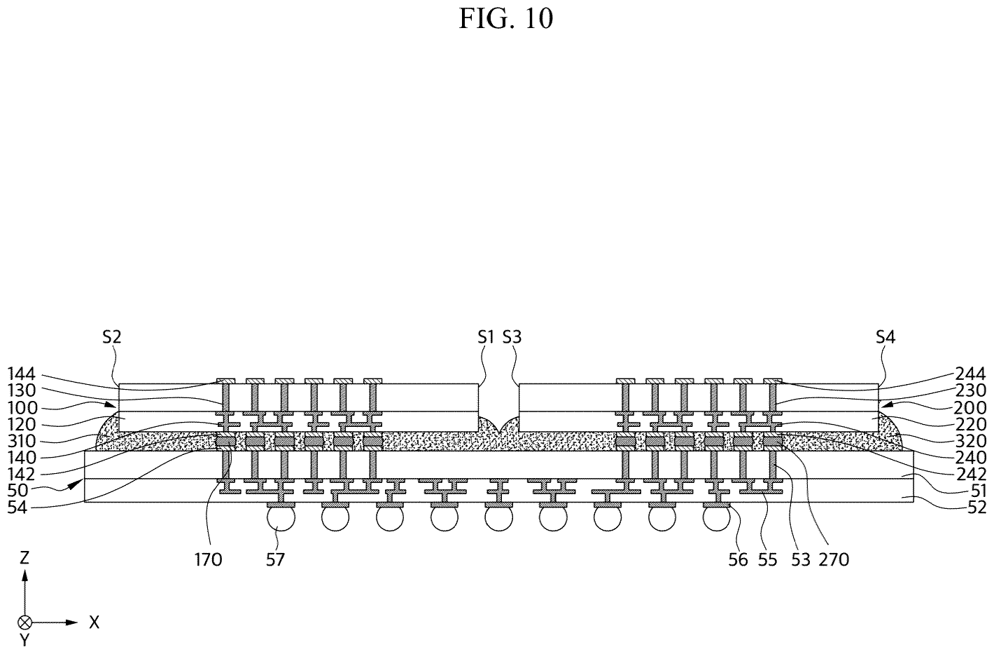

Further, referring to FIG. 10, the first fillet 310 and the second fillet 320 may be formed.

According to one or more example embodiments, the first fillet 310 may fill the space between the first semiconductor chips 100 and the buffer chip 50. The first fillet 310 that fills the space between the first semiconductor chips 100 and the buffer chip 50 may protrude to the sides of the first semiconductor chips 100. For example, the first fillet 310, which fills the space between the lower surface of the first semiconductor chip 100 and the upper surface of the buffer chip 50, may protrude to the outside of the first side surface S1 and the second side surface S2.

Likewise, the second fillet 320 may fill the space between the second semiconductor chips 200 and the buffer chip 50. The second fillet 320 that fills the spaces between the second semiconductor chips 200 and the buffer chip 50 may protrude to the sides of the second semiconductor chips 200. For example, the second fillet 320 that fills the spaces between the lower surface of the second semiconductor chip 200 and the upper surface of the buffer chip 50 may protrude to the outside of the third side surface S3 and the fourth side surface S4.

According to one or more example embodiments, the first fillet 310 protrudes outward more than the first side surface S1, and the second fillet 320 protrudes outward more than the third side surface S3, and may be merged or joined on the buffer chip 50. This may be due to the short distance between the first semiconductor chip 100 and the second semiconductor chip 200. In order to miniaturize the semiconductor package, the first semiconductor chips 100 and the second semiconductor chip 200 may be placed close to each other.

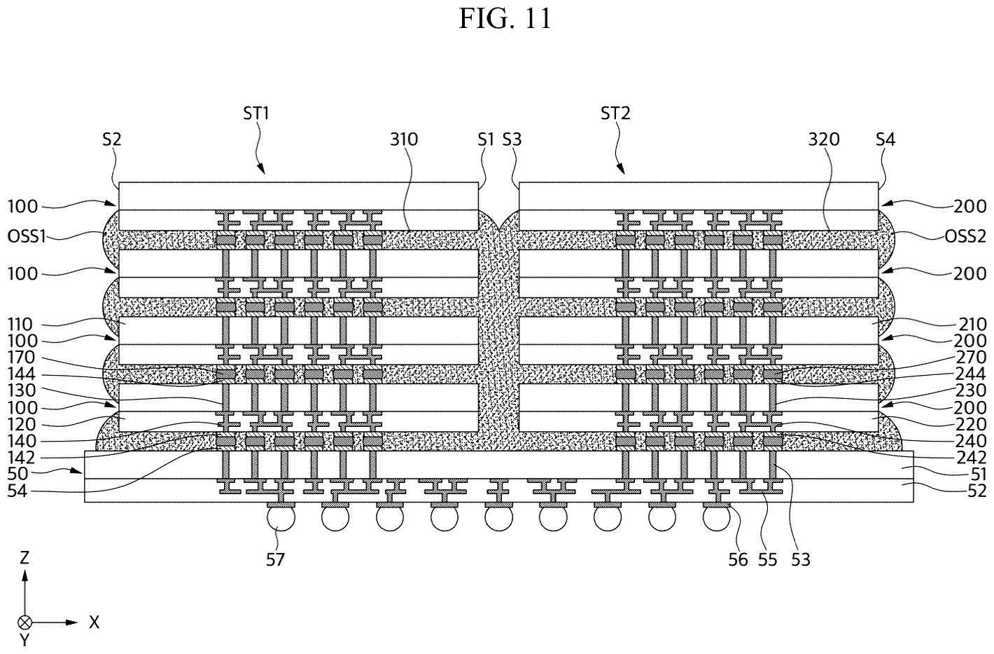

Further, referring to FIG. 11, one or more additional first semiconductor chips 100 and one or more additional second semiconductor chips 200 may be stacked in the third direction Z to form the first stack ST1 and the second stack ST2. The first fillet 310 may be formed between the plurality of first semiconductor chips 100, for example, between two vertically adjacent chips. The second fillet 320 may be formed between the plurality of second semiconductor chips 200. Between the plurality of first semiconductor chips 100 and the plurality of second semiconductor chips 200, the first fillet 310 which protrudes more than the first side surface S1 and the second fillet 320 which protrudes more than the third side surface S3 may be merged or joined.

FIG. 11 illustrates that the first fillet 310 and the second fillet 320 are completely merged between the first stack ST1 and the second stack ST2. However, the present disclosure is not limited thereto. For example, during the process of merging the first fillet 310 and the second fillet 320, one or more voids may be formed inside. Therefore, one or more air gaps may be disposed between the first fillet 310 and the second fillet 320.

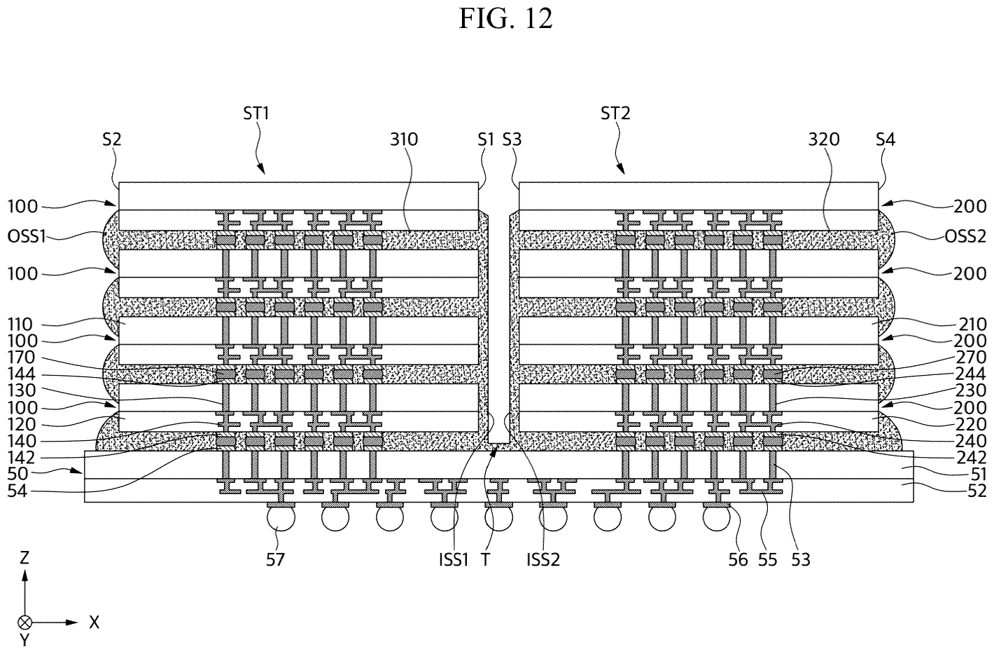

Further, referring to FIG. 12, the trench T may be formed between the first stack ST1 and the second stack ST2. For example, the trench T may be formed through a blade sawing process. The trench T may separate the merged first fillet 310 and the second fillet 320. The trench T may be spaced apart from the buffer chip 50 in the third direction Z. Through the trench T, the first inner surface ISS1 of the first fillet 310 and the second inner surface ISS2 of the second fillet 320 may be exposed. The first inner surface ISS1 and the second inner surface ISS2, which are cross sections formed through the blade sawing process, may be flat.

Meanwhile, in order to prevent damage to the buffer chip 50 during the formation of the trench T through the blade sawing process, the trench T may be formed to be spaced apart from the buffer chip 50 in the third direction Z without exposing the buffer chip 50.

Further, referring to FIG. 2, the molding film 400 may be formed. The molding film 400 may fill the trench T. The separating part 410 may be formed within the trench T. The cover 420 may be formed on the first outer surface OSS1 and the second outer surface OSS2.

According to one or more example embodiments, the larger the gap between the first stack ST1 and the second stack ST2, the more likely it is that warpage of the semiconductor package will occur during the semiconductor package manufacturing process. Therefore, it is required that the gap between the first stack ST1 and the second stack ST2 is minimized. Meanwhile, if the first fillet 310 leaked to the outside of the first semiconductor chip 100 due to the close placement of the first stack ST1 and the second stack ST2 and the second fillet 320 that leaked to the outside of the second semiconductor chip 200 are merged or joined, one or more voids may be formed within the first fillet 310 and the second fillet 320. When voids within the first fillet 310 and the second fillet 320 are not filled with the molding film 400, the reliability of the semiconductor package may be reduced. Therefore, the reliability of the semiconductor package may be improved by removing the voids by forming the trench T within the first fillet 310 and the second fillet 320 that are only partially joined between the first stack ST1 and the second stack ST2.

FIGS. 13 to 15 are diagrams illustrating intermediate processes for explaining a method of manufacturing a semiconductor package, according to one or more embodiments. For reference, FIGS. 13 to 15 are diagrams for explaining a method of manufacturing the semiconductor package illustrated in FIG. 5. Further, for reference, FIG. 13 is a diagram illustrating an intermediate process after FIG. 10. For convenience of explanation, differences from those described with reference to FIGS. 9 to 12 will be mainly explained.

Referring to FIGS. 10 and 13, a void V may be formed between the first fillet 310 and the second fillet 320.

If the first fillet 310 protruding more than the first side surface S1 of each of the plurality of first semiconductor chips 100 and the second fillet 320 protruding more than the third side surface S3 of each of the plurality of second semiconductor chips 200 are not large enough to be completely merged, the void V surrounded by the first fillet 310 and the second fillet 320 may be formed. For example, when a distance between the first stack ST1 and the second stack ST2 is close enough for the first fillet 310 and the second fillet 320 to be partially merged but not to be completely merged, and volumes of the first fillet 310 and the second fillet 320 are relatively small, then, the void V may be formed.

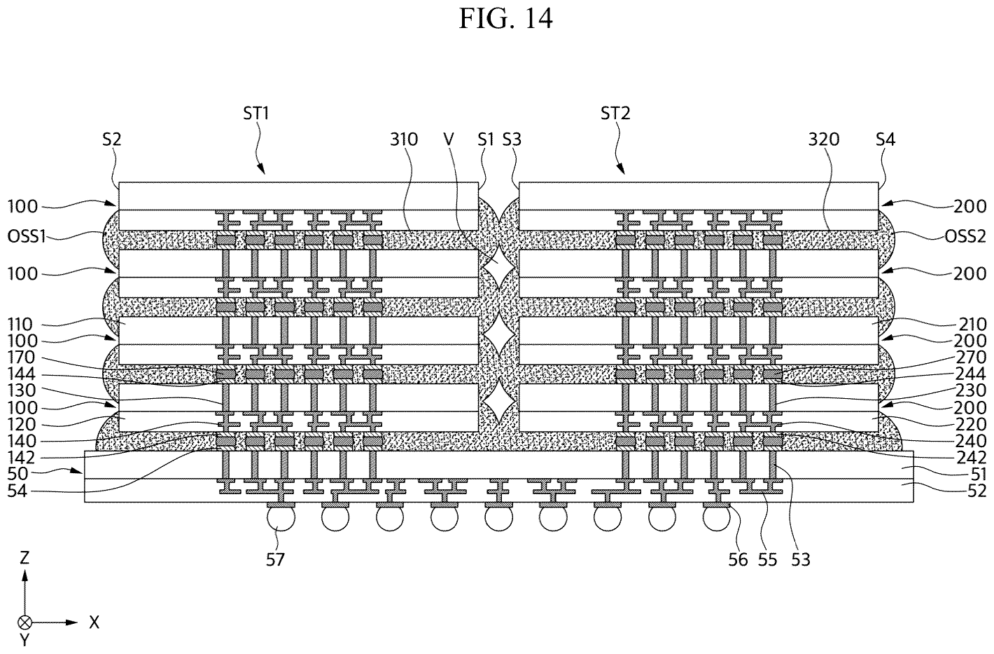

Further, referring to FIG. 14, each of the plurality of first semiconductor chips 100 and the plurality of second semiconductor chips 200 may be stacked in the third direction Z to form the first stack ST1 and the second stack ST2. A plurality of voids V may be formed between the first stack ST1 and the second stack ST2.

Further, referring to FIG. 5, the trench T may be formed between the first stack ST1 and the second stack ST2. The trench T may penetrate the first fillet 310 and the second fillet 320 that are merged or joined between the first stack ST1 and the second stack ST2 and open the void Vin FIG. 14 surrounded by the first fillet 310 and the second fillet 320. The void V in FIG. 14 is opened by the trench T, and one or more recesses may be formed in the first fillet 310 and the second fillet 320.

Further, referring to FIG. 5, the molding film 400 may be formed. The molding film 400 may fill the trench T. The separating part 410 may be formed within the trench T. The separating part 410 may fill the recess part RCS.

In the above, various example embodiments of the present disclosure are described in detail. However, it will be apparent to those with average knowledge in the technical field that scope of rights of this disclosure is not limited thereto, and various modifications and variations are possible without departing from the technical spirit of the present disclosure as set forth in the claims. Further, the above-described example embodiment may be implemented with one or more elements deleted, and each example embodiment may be implemented in combination with each other.

What is claimed is:

1. A semiconductor package comprising:
a first stack comprising a plurality of first semiconductor chips that are stacked in a first direction;
a first fillet between the plurality of first semiconductor chips;
a second stack that is spaced apart from the first stack in a second direction intersecting the first direction, and comprises a plurality of second semiconductor chips that are stacked in the first direction; and
a second fillet between the plurality of second semiconductor chips,
wherein each of the plurality of first semiconductor chips comprises:
a first side surface facing the second stack; and
a second side surface disposed on an opposite side of the first side surface,
wherein each of the plurality of second semiconductor chips comprises:
a third side surface facing the first stack; and
a fourth side surface disposed on an opposite side of the third side surface,
wherein the first fillet comprises a first inner surface on at least a portion of the first side surfaces, and facing the second stack,
wherein the second fillet comprises a second inner surface on at least a portion of the third side surfaces, and facing the first inner surface, and
wherein the first inner surface and the second inner surface are flat along the first direction in which the plurality of first semiconductor chips are stacked.

2. The semiconductor package of claim 1, wherein the first fillet further comprises a first outer surface on at least a portion of the second side surfaces,
wherein the first outer surface is an opposite surface of the first inner surface based on the first semiconductor chips, and
wherein the first outer surface protrudes more convexly outward than the second side surface.

3. The semiconductor package of claim 2, wherein, in the second direction, the first fillet has a maximum thickness between the first inner surface and the first side surface that is smaller than a maximum thickness of the first fillet between the first outer surface and the second side surface.

4. The semiconductor package of claim 1, further comprising a molding film that surrounds the first stack and the second stack,
wherein the molding film between the first inner surface and the second inner surface.

5. The semiconductor package of claim 4, wherein the molding film has a lowest bottom surface between the first inner surface and the second inner surface, and
wherein the lowest bottom surface is at a level higher than a lowest bottom surface of the first fillet and a lowest bottom surface of the second fillet.

6. The semiconductor package of claim 1, wherein the first fillet further comprises one or more recesses on the first inner surface.

7. The semiconductor package of claim 1, wherein the first side surface and the third side surface has a distance that is 40 to 150 micrometers (μm).

8. The semiconductor package of claim 1, further comprising a buffer chip below the first stack and the second stack in the first direction,
wherein the first fillet is between the first stack and the second stack, and
wherein the second fillet is between the second stack and the buffer chip.

9. The semiconductor package of claim 8, wherein the first fillet and the second fillet are connected to each other on the buffer chip.

10. The semiconductor package of claim 8, wherein the first fillet and the second fillet are spaced apart on the buffer chip.

11. The semiconductor package of claim 10, wherein a portion of the first fillet below the first stack protrudes more toward the second stack than the first inner surface.

12. The semiconductor package of claim 8, further comprising a buffer chip connecting bump on a lower surface of the buffer chip,
wherein the buffer chip connecting bump overlaps at least a portion of the first stack or the second stack in first the direction, and
wherein the first stack and the second stack are connected to the buffer chip connecting bump.

13. A semiconductor package comprising:
a first stack comprising a plurality of first semiconductor chips that are stacked in a first direction;
a first fillet between the plurality of first semiconductor chips;
a second stack that is spaced apart from the first stack in a second direction intersecting the first direction, and comprises a plurality of second semiconductor chips that are stacked in the first direction;
a second fillet between the plurality of second semiconductor chips; and
a molding film that surrounds the first stack and the second stack,
wherein the molding film comprises a separating part between the first stack and the second stack,
wherein the separating part extends along the first direction, and
wherein the separating part has sides facing the first stack and the second stack are flat.

14. The semiconductor package of claim 13, further comprising a buffer chip below the first stack and the second stack,
wherein the first fillet is between the first stack and the buffer chip,
wherein the second fillet is between the second stack and the buffer chip, and
wherein the separating part has a lowest bottom surface that is spaced apart from the buffer chip.

15. The semiconductor package of claim 13, wherein each of the plurality of first semiconductor chips comprises:
a first side surface facing the second stack; and
a second side surface disposed on an opposite side of the first side surface,
wherein each of the plurality of second semiconductor chips comprises:
a third side surface facing the first stack; and
a fourth side surface disposed on an opposite side of the third side surface,
wherein the first fillet comprises:
a first inner surface on at least a portion of the first side surfaces, and facing the second stack,
a first outer surface on at least a portion of the second side surfaces, the first outer surface being an opposite surface of the first inner surface based on the first semiconductor chips,
wherein the first inner surface is in contact with the separating part, and
wherein the first outer surface protrudes more outward than the second side surface.

16. The semiconductor package of claim 15, wherein the first outer surface has a curved shape.

17. The semiconductor package of claim 15, wherein the first outer surface is flat along the first direction.

18. The semiconductor package of claim 13, wherein the molding film has an upper surface coplanar or aligned with an upper surface of the first stack and an upper surface of the second stack.

19. The semiconductor package of claim 13, wherein the plurality of first semiconductor chips comprise a first bottom part semiconductor chip,
wherein the first fillet comprises:
a first bottom part fillet below the first bottom part semiconductor chip; and
a first upper part fillet above the first bottom part semiconductor chip, and
wherein the first bottom part fillet protrudes more laterally than the first upper part fillet. 20 A semiconductor package comprising:
a buffer chip;
a first stack on the buffer chip, the first stack comprising a plurality of first semiconductor chips that are stacked in a first direction;
a first fillet on the buffer chip, and the first fillet filling spaces between the plurality of first semiconductor chips;
a second stack that is spaced apart from the first stack on the buffer chip in a second direction intersecting the first direction, and comprises a plurality of second semiconductor chips that are stacked in the first direction;
a second fillet on the buffer chip, and the second fillet filling spaces between the plurality of second semiconductor chips;
a molding film that surrounds the first stack and the second stack; and
a buffer chip connecting bump on a lower surface of the buffer chip,
wherein the buffer chip connecting bump overlaps at least a portion of the first stack or the second stack in the first direction,
wherein the first fillet between the buffer chip and the first stack and the second fillet between the buffer chip and the second stack are connected,
wherein the molding film comprises a separating part extending between the first stack and the second stack along the first direction,
wherein a side of the separating part is flat,
wherein the separating part is spaced apart from the buffer chip, and
wherein the first stack and the second stack are connected to the buffer chip connecting bump.
